(19) United States
(12) Patent Application Publication
(10) Pub. No.: US 2012/0211051 A1
(43) Pub. Date: Aug. 23, 2012

(54) Heat sink systems for large-size photovoltaic receiver

(76) Inventors: Alexander Levin, Binyamina (IL); Hanan Levin, South Caulfield (AU)

(21) Appl. No.: 12/932,233

(22) Filed: Feb. 22, 2011

(51) Int. Cl. H01L 31/052

(52) U.S. Cl. 136/246

(57) ABSTRACT

An invention proposes a heat sink system for large-size photovoltaic receivers of tower-type solar power stations with application of an array of heliostats intended to concentrate solar radiation on the photovoltaic receiver.

The heat sink system is designed as a two-phase thermo-siphon and it can ensure a stable temperature on all photovoltaic cells installed on the large-size receiver with very small deviations of the temperatures from one photovoltaic cell to another.

### STATEMENT REGARDING FEDERALLY SPONSORED RESEARCH

Not applicable.

### BACKGROUND OF THE INVENTION

This invention proposes a heat sink system for large-size photovoltaic receivers of tower-type solar power stations with application of an array of heliostats intended to concentrate solar radiation on the photovoltaic receiver.

The problem of effective chilling of photovoltaic cells installed on a large-size receiver presents a serious technical challenge. Significant deviations in temperatures of different PV cells cause significant decrease in efficiency of the entire photovoltaic receiver.

US patent application No. 20070089775 describes a photovoltaic cell module for a receiver of solar radiation-based electrical power generating system. The module includes an assembly for extracting heat from the photovoltaic cells. The assembly includes a coolant chamber positioned behind and in thermal contact with the exposed surface of the photovoltaic cells. The coolant chamber includes an inlet for a coolant and an outlet for heated coolant. The assembly also includes a plurality of beads, rods, bars or balls of high thermal conductivity material in the coolant chamber that are in thermal contact with the photovoltaic cells and each other and together have a large surface area for heat transfer and define a three dimensional labyrinth that can conduct heat therethrough away from the photovoltaic cell or cells.

In particular, the applicant of this patent application has found that the above-described cell module makes it possible to extract sufficient heat generated by incident concentrated solar radiation so that the temperature difference between the inlet coolant temperature and the front faces of the photovoltaic cells is less than 40.degree. C., typically less than 30 degree C., more typically less than 25 degree C., and in recent test work less that 20 degree C., and that this result can be achieved with a low pressure drop of coolant, typically less than 100 kPa, typically less than 60 kPa, and more typically less than 40 kPa across the coolant inlet and coolant outlet of the cell module. The low pressure drop is an important consideration because it means that it is possible to minimize the energy requirements for circulating coolant through the module.

However, this technical solution cannot provide the temperature difference in the range of some Celsius degrees. In addition, there is a need in a pumping means for circulating the coolant.

U.S. patent application Ser. No. 12/583,447 to authors of this invention proposes to apply a two-phase thermo-siphon system for cooling the photovoltaic receiver.

The two-phase thermo-siphon system has following technical features;

1. It provides permanent wetting of the rear side an entire large-size metal plate with the photovoltaic cells installed on its forward side. This wetting should be with a low-boiling working medium (for example—acetone).

2. It operates with such working pressure in an evaporation chamber of the two-phase thermo-siphon that is very close to atmospheric pressure in order to ensure mechanical intact of this evaporation chamber.

3.The working pressure in the evaporation chamber is remaining to be very close to atmospheric pressure during the night time without solar radiation despite heat losses from the evaporation chamber of the two-phase thermo-siphon into the surroundings through the all walls of the evaporation chamber.

4. It is achieved by application of sealed containers with PCM (phase change material); melting temperature of this PCM is very close to operation temperature of the evaporation chamber at sunny hours.

5. A control block regulates operation of the condenser of the two-phase thermo-siphon in such manner that the operating pressure of the evaporation chamber remains very close to atmospheric pressure.

However, this technical solution is very cumbersome and expensive.

US patent application No. 20080314437 describes a multi-heliostat concentrating (MHC) system for utilizing sun energy, which has at least on MHC module. A MHC module has at least one optical concentrator having a focusing reflective surface, aperture and an optical axis. A plurality of heliostats, which are preferably located symmetrically relative to the optical axis of an optical concentrator simultaneously reflect sun radiation towards its aperture. Flux error correcting a flux homogenizing device disposed at the focal region of an optical concentrator provides for further concentrating and homogenizing the flux of the focused sun radiation. A receiver preferably comprising concentrated photovoltaic cells and an optional passive heat-sink provides for efficiently and economically generating electrical power.

This patent application does not give description of the passive heat sink system.

WO/2010/014310 to Kokotov et al. describes a solar power generation system includes a plurality of individual modules, each formed from a photovoltaic cell, a solar concentrator, a sealed evaporative cooling system and a heat sink. The solar concentrator focuses sunlight onto a front side the cell to generate electricity. The cooling system circulates a coolant in a liquid state to an evaporative cooling chamber having a wall defined at least partially by a back side of the cell to remove heat from the cell by direct contact between the coolant and the cell, and emits coolant in a vapor state to a condenser where the vapor coolant is condensed to a liquid state. The heat sink may be any suitable body of water, such that the condenser may be at least partially submerged therein. The modules are combined to form a platform that is rotated on the body of water by a drive device to provide tracking of the sun.

This technical solution is suitable only for small-size floating systems with photovoltaic cells oriented substantially horizontally.

Therefore, application of two-phase thermo-siphon system for cooling the large-size photovoltaic receiver seems an attractive technical solution, but in a cheaper and simpler form than it has been proposed in the U.S. patent application Ser. No. 12/583,447.

There is a technical problem to be solved for such two-phase thermo-siphon system: ensuring permanent wetting of the rear side an entire large-size metal plate with the photovoltaic cells installed on its forward side. This wetting should be by a liquid working medium with proper temperature of boiling in rare atmosphere (for example—water, methanol, ethanol, acetone). A preferable temperature of boiling ranges between 50° C. and 70° C.

Detailed description of thermo-siphons with regulation of their working pressure is presented in a book: EFFECTIVE HEAT EXCHANGERS WITH APPLICATION OF TWO-PHASE THERMO-SIPHONS, I. L. Pioro et al., Naukova Dumka, Kiev 1991 (in Russian). However, this book does not propose a simple and reliable design of a two-phase thermo-siphon with the required feature.

### SUMMARY OF THE INVENTION

The invention provides design of a large-size heat sink for photovoltaic power stations constructed as a photovoltaic receiver mounted on a tower and an array of heliostats directing reflected solar radiation on the photovoltaic receiver. The design has all required features described in the background of this invention. An evaporation chamber of the two-phase thermo-siphon includes following elements:

1. A large-size metal plate with the photovoltaic cells installed on its forward side, the rear side of this metal plate is provided with a capillary structure in a form of a capillary coating with open porosity.

2. Lateral walls and a rear wall of the evaporation chamber with an outlet connection for removal of vapors of the working medium to a condenser and an inlet connection for return of condensate of the working medium from the condenser into a distributing means installed on the rear upper section of the large-size metal plate.

3. The rear wall of the evaporation chamber is provided with an array of spacers preferably in the form of pins arranged perpendicularly to the plane of the rear wall. The distal ends of the pin-wise spacers can be provided with spring-wise members. It allows achieving uniform distribution of pressing forces for all the pin-wise spacers.

4. Flexibility of the rear wall is significantly higher than flexibility of the large-size metal plate with the photovoltaic cells installed on it.

Combination of the array of the pin-wise spacers with high flexibility of the rear wall of the evaporation chamber allows diminishing to minimum deformations of the large-size metal plate with the photovoltaic cells installed on its forward side.

It is known, than sufficiently small distances between the pin-wise spacer allows diminishing to negligible small values deflection of the large-size metal plate with the photovoltaic cells.

4. A safety valve (or valves), which provides fluid communication of the evaporation chamber interior with the atmosphere or with a vacuum pump in the case of excess of pressure in the interior of the evaporation chamber regarding the atmospheric pressure.

5. Several inlet and outlet connections serve for supply and removal of the working medium in its liquid and vaporous states.

6. The aforementioned distributing means, which is mounted in the upper inner space of the evaporation chamber and serves for uniform distribution of the liquid working medium along the upper edge of the porous coating.

An auxiliary pumping means is supplying the liquid working medium from the bottom section of the evaporator chamber into the inlet connection serving for feeding the liquid working medium into the inlet connection, especially, at the moment of starting operation and during operation itself. It allows compensating for condensate deficiency caused by condensation of the vaporous working medium on the walls of the evaporation chamber itself.

In another version of this invention, the liquid working medium fills the evaporation chamber until such level, that the lower section of the capillary coating is submerged into the liquid working medium. For certain technical parameters of the evaporation chamber, pumping ability of the capillary coating compensates for condensate deficiency caused by condensation of the vaporous working medium on the walls of the evaporation chamber itself.

Vapors of the working medium are removed from the evaporation chamber via the outlet connection and enter into a condenser, which is designed as a heat exchanger of a recuperation type with condensing the vapors of the working medium by surrounding air or by cooling water.

The evaporation chamber is provided with a sensor of internal pressure, which sends a signal to a control block. This control block regulates in accordance with a value of difference between the internal pressure and atmospheric pressure heat exchange rate in the condenser by adjusting flow rate of the cooling medium (surrounding air or cooling water).

Condensate is returning from the condenser into the evaporation chamber via its inlet connection and is supplied into the aforementioned distributing means.

In addition, there are the aforementioned vacuum pump and a cooler-separator, which are in a fluid communication with the condensing interior of the condenser and serves for removal of non-condensable gases from the interior of the two-phase thermo-siphon and recovery of the condensed working medium from the cooler-separator into the evaporation chamber.

At the night time the desired low pressure in the evaporation chamber is established by closing the aforementioned valve, which is installed on the fluid communication line between the condenser and the vacuum pump.

### BRIEF DESCRIPTION OF THE SEVERAL VIEWS OF THE DRAWING

FIG. 1 shows a general view of a solar power station with photovoltaic cells installed on a tower and an array of heliostats, which concentrate solar radiation on the photovoltaic cells.

FIGS. 2a and 2b show the inside view of the large-size metal plate and its vertical transverse cross-section.

FIG. 3 demonstrates an isometric view of a rear wall of an evaporation chamber with an array of pin-wise spacers.

FIG. 4 shows a transverse cross-section of a rear wall section of the evaporation chamber with the pin-wise spacers installed in openings formed in it.

FIG. 5 shows a vertical cross-section of an evaporation chamber.

FIG. 6 shows a general scheme of a heat sink system that includes vertical cross-section of the evaporation chamber, a condenser and an auxiliary appliances, which serve as a heat sink for cooling the photoelectrical cells; this system includes in addition an auxiliary pumping means arranged outside the evaporation chamber.

### DESCRIPTION OF PREFERRED EMBODIMENTS

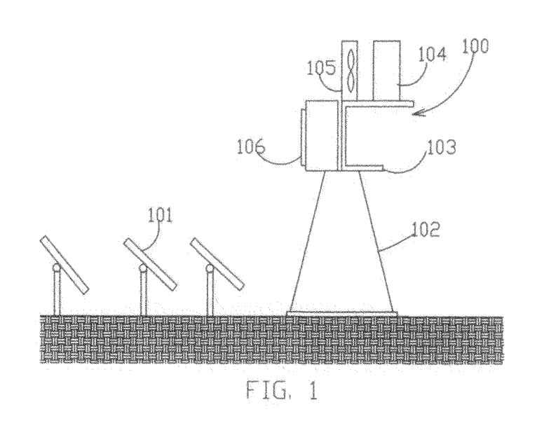

FIG. 1 shows a general view of a solar power station with photovoltaic cells installed on a tower and an array of heliostats, which concentrate solar radiation on the photovoltaic cells.

The solar power station 100 comprises: heliostats 101; tower 102; a two-phase thermo-siphon 100, which consists of an evaporation chamber 103 with photovoltaic cells 106 installed on the outer surface of the forward wall of the evaporation chamber 103, fan 105 and condenser 104.

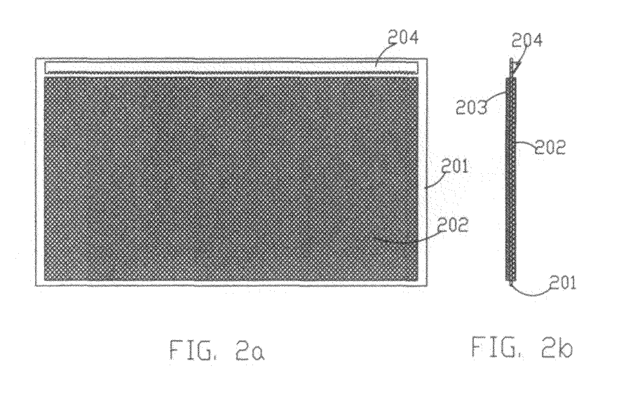

FIGS. 2a and 2b show a inside view of the large-size metal plate and its vertical transverse cross-section.

It comprises: a metal plate 201 with a porous capillary coating 202 on its rear side; and photovoltaic cell 203 installed on the forward side of the metal plate 201. In addition, there is a distributing means 204 installed on the upper section of the internal side of the metal plate 201.

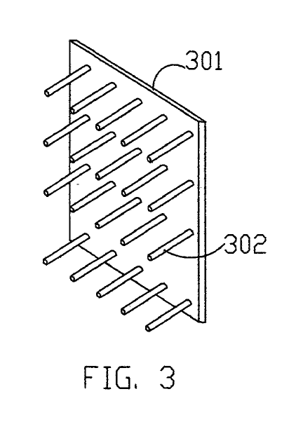

FIG. 3 demonstrates an isometric view of a rear wall of an evaporation chamber with an array of pin-wise spacers. It comprises plate 301 and spacers designed as an array of pins 302.

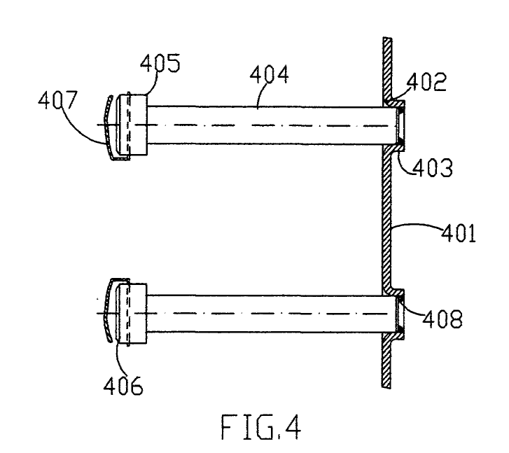

FIG. 4 shows a transverse cross-section of a rear wall section of the evaporation chamber with the pin-wise spacers installed in openings formed in it.

It comprises plate 401 with openings 402 and their flanging 403. Pressure pins 404 with heads 405 are installed by their proximal ends in flanging 403; heads 405 are provided with slots 406, which serves for fastening flat springs 407. The proximal ends of pressure pins 404 are joined with flanging 403 by welding 408. In another case, soldering or brazing can be used for this joining.

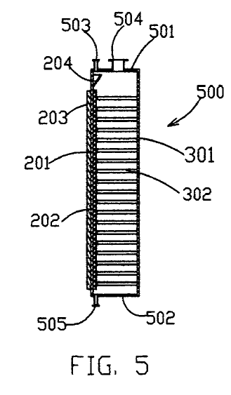

FIG. 5 shows a vertical cross-section of an evaporation chamber 500. It comprises the metal plate 201 with the porous capillary coating 202 on its rear side; and the photovoltaic cell 203 installed on the forward side of the metal plate 201. In addition, there is the distributing means 204 installed on the upper section of the internal side of the metal plate 201. A rear wall of the evaporation chamber comprises plate 301 and spacers designed as the array of pins 302. The metal plate 201 and plate 301 are joined by lateral walls, which include an upper wall 501 and the lower wall 502. The upper wall 501 is provided with an inlet connection 503 and an outlet connection 504. The lower wall 502 is provided with an outlet connection 505.

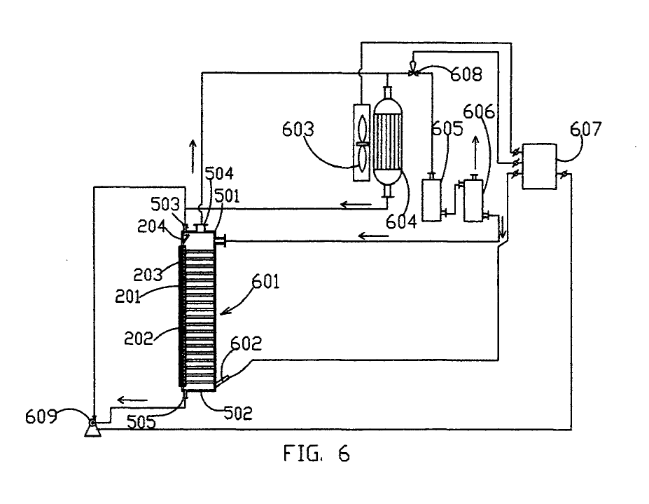

FIG. 6 shows a general scheme of a heat sink system that includes vertical cross-section of an evaporation chamber, a condenser and an auxiliary appliances, which serve as a heat sink for cooling the photoelectrical cells; this system includes in addition an auxiliary pumping means arranged outside the evaporation chamber.

An evaporation chamber 601 comprises the metal plate 201 with the porous capillary coating 202 on its rear side; and the photovoltaic cell 203 installed on the forward side of the metal plate 201. In addition, there is the distributing means 204 installed on the upper section of the internal side of the metal plate 201. A rear wall of the evaporation chamber comprises plate 301 and spacers designed as the array of pins 302. The metal plate 201 and plate 301 are joined by lateral walls, which include an upper wall 501 and the lower wall 502. The upper wall 501 is provided with an inlet connection 503 and an outlet connection 504. The lower wall 502 is provided with an outlet connection 505.

In addition, the evaporation chamber 601 is provided with a pressure gauge 602.

The systems comprises in addition fan 603; condenser 604; an auxiliary pumping means 609; a vacuum pump 605; cooler-separator 606; a control block 607 and valve 608 regulated by the control block 607.

Condenser 604, which is in fluid communication with the outlet connection 504 and the inlet connection 503, serves for condensing vapors of the working medium removed from the evaporation chamber 601.

Fan 603 supplies a cooling air into condenser 604.

A vacuum pump 605 and cooler-separator 606 are energized during beginning operation of the heat sink system with allowing withdrawing non-condensable gases (air) via valve 608 from the interior of the evaporation chamber 601 and condenser 604.

Operation of the entire heat sink system and its elements such as fan 603, and valve 608 are regulated by the control block 607 according to value of internal pressure measured by the pressure gauge (manometer) 602 and presence of non-condensable gases in the interior of the evaporation chamber 601 and condenser 604.

The heat sink system operates in a following manner: supply of the liquid working medium into the distributing means 204 allows wetting entire capillary coating 202 of the metal plate 201. It ensures effective cooling of photovoltaic cells 203 installed on the outer surface of this metal plate 201.

The evaporated working medium is expelled via the outlet connection 504 into condenser 604.

The condensed working medium is returning into the evaporation chamber 601 via the inlet connection 503.

An auxiliary pumping means 609 is supplying the liquid working medium from the bottom section of the evaporator chamber 601 into the inlet connection serving for feeding the liquid working medium into the inlet connection 503, especially at the moment of starting operation and during operation itself. It allows to compensate for the condensate deficiency caused by condensation of the vaporous working medium on the walls of the evaporation chamber itself. The internal pressure in the evaporator chamber 601 is lower than the atmospheric pressure. It is ensured by the liquid working medium with sufficiently high temperature of boiling in rare air (this temperature ranges preferably in the interval of 50° C.÷70° C.).

1. A large-size photovoltaic receiver of a tower-type solar power station with application of an array of heliostats for concentration of solar radiation on said large-size photovoltaic receiver; said large-size photovoltaic receiver is designed as a heat sink unit with photovoltaic cells mounted on the outer side of said heat sink unit; said heat sink unit comprises an evaporator chamber and a condenser being in fluid communication with said evaporation chamber ;said condenser is positioned at somewhat higher level regarding said evaporation chamber; said evaporation chamber comprises :
a large-size metal plate with photovoltaic cells installed on its external surface, the internal surface of this metal plate is provided with a capillary structure with open porosity;
a distributing means installed on the upper section of the internal side of said large-size metal plate;
said evaporation chamber includes in addition: lateral walls and a rear wall with an outlet connection for removal of vapors of the working medium and at least one inlet connection for supply of said liquid working medium into said distributing means, and an array of spacers installed on the internal side of said rear wall;
said condenser is designed as a heat exchanger of the recuperative type; said condenser is provided with inlet and outlet connections, which are in fluid communication with said outlet and inlet connections of said evaporation chamber;
a vacuum pump and a cooler-separator, which are in fluid communication with said condenser and said evaporation chamber; said vacuum pump and cooler-separator serve for periodical removal of non-condensable gases from the interiors of said condenser and said evaporation chamber;
a pressure gauge, which is measuring the internal pressure in said evaporation chamber;
a cooler serving for cooling and condensation of said working medium vapors in said condenser; said vacuum pump and said cooler ensure such pressure of said working medium in said evaporation chamber and said condenser, which is lower than the atmospheric pressure;
a control block that regulates the rate of cooling said working medium vapors in said condenser.

2. A large-size photovoltaic receiver of a tower-type solar power station as claimed in claim 1, wherein the rear wall of the evaporation chamber comprises a plate ith openings and their flanging; pressure pins with heads are installed by their proximal ends in said flanging and joined with them by welding; said heads are provided with slots, which serve for fastening spring-wise members.

3. A large-size photovoltaic receiver of a tower-type solar power station as claimed in claim 2, wherein the pressure pins are joined with the flanging of the openings by soldering.

4. A large-size photovoltaic receiver of a tower-type solar power station as claimed in claim 2, wherein the pressure pins are joined with the flanging of the openings by brazing.

5. A large-size photovoltaic receiver of a tower-type solar power station as claimed in claim 2, wherein the spring-wise members are designed as flat springs.

6. A large-size photovoltaic receiver of a tower-type solar power station as claimed in claim 1, wherein the working medium is water.

7. A large-size photovoltaic receiver of a tower-type solar power station as claimed in claim 1, wherein the working medium is methanol.

8. A large-size photovoltaic receiver of a tower-type solar power station as claimed in claim 1, wherein the working medium is ethanol.

9. A large-size photovoltaic receiver of a tower-type solar power station as claimed in claim 1, wherein the working medium is acetone.

10. A large-size photovoltaic receiver of a tower-type solar power station as claimed in claim 1, wherein there is a valve, which is installed on the fluid communication line between the condenser and the vacuum pump.

11. A large-size photovoltaic receiver of a tower-type solar power station as claimed in claim 1, wherein flexibility of the rear wall is higher than flexibility of the large-size metal plate.
